(19) United States
(12) Patent Application Publication
(10) Pub. No.: US 2008/0130367 A1
(43) Pub. Date: Jun. 5, 2008

(54) Byte-Erasable Nonvolatile Memory Devices

(75) Inventors: Sung-Taeg Kang, Seoul (KR); Hee-Seog Jeon, Gyeonggi-do (KR); Jeong-Uk Han, Gyeonggi-do (KR); Chang-Hun Lee, Gyeonggi-do (KR); Bo-Young Seo, Gyeonggi-do (KR); Chang-Min Jeon, Seoul (KR); Eun-Mi Hong, Busan (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/027,735

(22) Filed: Feb. 7, 2008

Related U.S. Application Data
(63) Continuation of application No. 11/427,211, filed on Jun. 28, 2006.

(30) Foreign Application Priority Data
Jul. 13, 2005 (KR) 2005-63391
Sep. 9, 2005 (KR) 2005-83981

(51) Int. Cl. G11C 16/14

(52) U.S. Cl. 365/185.13

(57) ABSTRACT

A nonvolatile memory device includes a semiconductor well region of first conductivity type on a semiconductor substrate and a common source diffusion region of second conductivity type extending in the semiconductor well region and forming a P-N rectifying junction therewith. A byte-erasable EEPROM memory array is provided in the semiconductor well region. This byte-erasable EEPROM memory array is configured to support independent erasure of first and second pluralities of EEPROM memory cells therein that are electrically connected to the common source diffusion region.

### REFERENCE TO PRIORITY APPLICATIONS

This application is a continuation of U.S. application Ser. No. 11/427,211, filed Jun. 28, 2006, which claims priority to Korean Application Nos. 2005-63391, filed Jul. 13, 2005, and 2005-83981, filed Sep. 9, 2005, the disclosures of which are hereby incorporated herein by reference.

### FIELD OF THE INVENTION

The present invention relates to integrated circuit memory devices and, more particularly, to nonvolatile memory devices and methods of fabricating nonvolatile memory devices.

### BACKGROUND OF THE INVENTION

One class of nonvolatile memory devices includes electrically erasable programmable read only memory (EEPROM), which may be used in many applications including embedded applications and mass storage applications. In typical embedded applications, an EEPROM device may be used to provide code storage in personal computers or mobile phones, for example, where fast random access read times may be required. Typical mass storage applications include memory card applications requiring high capacity and low cost.

One category of EEPROM devices includes NAND-type flash memories, which can provide a low cost and high capacity alternative to other forms of nonvolatile memory. A typical NAND-type flash memory includes a plurality of NAND-type strings therein that are disposed side-by-side in a semiconductor substrate. Each of these NAND-type strings may be associated with respective bit lines that are connected to a page buffer. In some cases, the NAND-type strings may be configured to provide byte-erase capability in addition to a more conventional block erase capability. Examples of byte-erasable EEPROM memory devices are disclosed in U.S. Pat. No. 7,006,381 to Dormans et al. and in an article entitled “Device Architecture and Reliability Aspects of a Novel 1.22 um² EEPROM cell in 0.18 um Node for Embedded Application,” Microelectronics Engineering 72, pp. 415-420 (2004).

Each EEPROM cell within a NAND-type string includes a floating gate electrode and a control gate electrode, which is electrically connected to a respective word line. These EEPROM cells may be cells that support a single or a multi-level programmed state. EEPROM cells that support only a single programmed state are typically referred to as single level cells (SLC). In particular, an SLC may support an erased state, which may be treated as a logic 1 storage value, and a programmed state, which may be treated as a logic 0 storage value. The SLC may have a negative threshold voltage (Vth) when erased (e.g., −3V<Vth<−1V) and a positive threshold voltage when programmed (e.g., 1V<Vth<3V). This programmed state may be achieved by setting a corresponding bit line to a logic 0 value (e.g., 0 Volts), applying a program voltage (Vpgm) to a selected EEPROM cell and applying a pass voltage (Vpass) to the unselected EEPROM cells within a string.

The programmed state or erased state of an EEPROM cell may be detected by performing a read operation on a selected cell. As will be understood by those skilled in the art, a NAND string will operate to discharge a precharged bit line BL when a selected cell is in an erased state and a selected word line voltage (e.g., 0 Volts) is greater than the threshold voltage of the selected cell. However, when a selected cell is in a programmed state, the corresponding NAND string will provide an open circuit to the precharged bit line because the selected word line voltage (e.g., 0 Volts) is less than the threshold voltage of the selected cell and the selected cell remains “off”. Other aspects of NAND-type flash memories are disclosed in U.S. application Ser. No. 11/358,648, filed Feb. 21, 2006, and in an article by Jung et al., entitled “A 3.3 Volt Single Power Supply 16-Mb Nonvolatile Virtual DRAM Using a NAND Flash Memory Technology,” IEEE Journal of Solid-State Circuits, Vol. 32, No. 11, pp. 1748-1757, November (1997), the disclosures of which are hereby incorporated herein by reference.

### SUMMARY OF THE INVENTION

Embodiments of the invention including nonvolatile memory devices having byte-erase capability. These memory device include a byte-erasable EEPROM memory array that is configured to support independent erasure of first and second pluralities of EEPROM memory cells that share a first semiconductor well region within a substrate and are electrically coupled by first and second byte selection transistors, respectively, to a global control line. This byte-erasable EEPROM memory array further includes a first local control line, which is electrically coupled to control electrodes of the first plurality of EEPROM cells and a first current carrying terminal of the first byte selection transistor, and a second local control line, which is electrically coupled to control electrodes of the second plurality of EEPROM cells and a first current carrying terminal of the second byte selection transistor. This first and second local control lines may be collinear and extend across the first semiconductor well region.

According to additional aspects of these nonvolatile memory devices, the first semiconductor well region is a region of first conductivity type (e.g., P-type) and the first byte selection transistor is formed within a second semiconductor well region of second conductivity type (e.g., N-type) that forms a P-N rectifying junction with the first semiconductor well region of first conductivity type. Each of the first and second pluralities of EEPROM memory cells can be a 2T or 3T EEPROM cell. A 2T EEPROM cell can include an NMOS transistor and a EEPROM transistor connected in series and a 3T EEPROM cell can include a pair of NMOS transistors and an EEPROM transistor connected in series. According to still further aspects of these embodiments, the first and second pluralities of EEPROM memory cells may share a common source line that extends across the first semiconductor well region. This common source line may include a common source line diffusion region of second conductivity type that is formed within the first semiconductor well region using selective dopant implantation and drive-in/diffusion steps.

According to still further embodiments of the invention, a nonvolatile memory device is provided that includes a semiconductor well region of first conductivity type on a semiconductor substrate and a byte-erasable EEPROM memory array in the semiconductor well region. The byte-erasable EEPROM memory array is configured to support independent erasure of first and second pluralities of EEPROM memory cells therein that share a ground selection line extending opposite the semiconductor well region. The first and second pluralities of EEPROM memory cells include EEPROM transistors having channel regions of first conductivity type that form non-rectifying junctions with the semiconductor well region.

Additional embodiments of the invention include a semiconductor well region of first conductivity type on a semiconductor substrate. This semiconductor well region includes a common source diffusion region of second conductivity type therein that forms a P-N rectifying junction with the semiconductor well region. A byte-erasable EEPROM memory array is provided in the semiconductor well region. The byte-erasable EEPROM memory array is configured to support independent erasure of first and second pluralities of EEPROM memory cells therein that are electrically connected to the common source diffusion region.

### BRIEF DESCRIPTION OF THE DRAWINGS

FIG. 1 is an electrical schematic of a byte-erasable EEPROM memory device according to an embodiment of the present invention.

FIG. 2A is an electrical schematic of a portion of the EEPROM memory device of FIG. 1 that highlights the state of applied voltages during a byte program operation.

FIG. 2B is an electrical schematic of a portion of the EEPROM memory device of FIG. 1 that highlights the state of applied voltages during a byte erase operation.

FIG. 2C is an electrical schematic of a portion of the EEPROM memory device of FIG. 1 that highlights the state of applied voltages during a byte read operation.

FIG. 3 is an electrical schematic of a byte-erasable EEPROM memory device according to another embodiment of the present invention.

FIG. 4A is an electrical schematic of a portion of the EEPROM memory device of FIG. 3 that highlights the state of applied voltages during a byte program operation.

FIG. 4B is an electrical schematic of a portion of the EEPROM memory device of FIG. 3 that highlights the state of applied voltages during a byte erase operation.

FIG. 5 is a layout schematic that illustrates a portion of the byte-erasable EEPROM memory device of FIG. 3.

FIG. 6A is an enlarged layout schematic of a byte-erasable EEPROM memory device that illustrates a central portion of the layout schematic of FIG. 5, which is highlighted with dotted lines as region A.

FIG. 6B is a cross-sectional view of the EEPROM memory device of FIG. 6A, taken along line 6B-6B′ in FIG. 6A.

FIG. 6C is a cross-sectional view of the EEPROM memory device of FIG. 6A, taken along line 6C-6C′ in FIG. 6A.

FIG. 7A is an enlarged layout schematic of a byte-erasable EEPROM memory device that illustrates a left-side portion of the layout schematic of FIG. 5, which is highlighted with dotted lines as region B.

FIG. 7B is a cross-sectional view of the EEPROM memory device of FIG. 7A, taken along line 7B-7B′ in FIG. 7A.

FIG. 7C is a cross-sectional view of the EEPROM memory device of FIG. 7A, taken along line 7C-7C′ in FIG. 7A.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout and signal lines and signals thereon may be referred to by the same reference characters. Signals may also be synchronized and/or undergo minor Boolean operations (e.g., inversion) without being considered different signals.

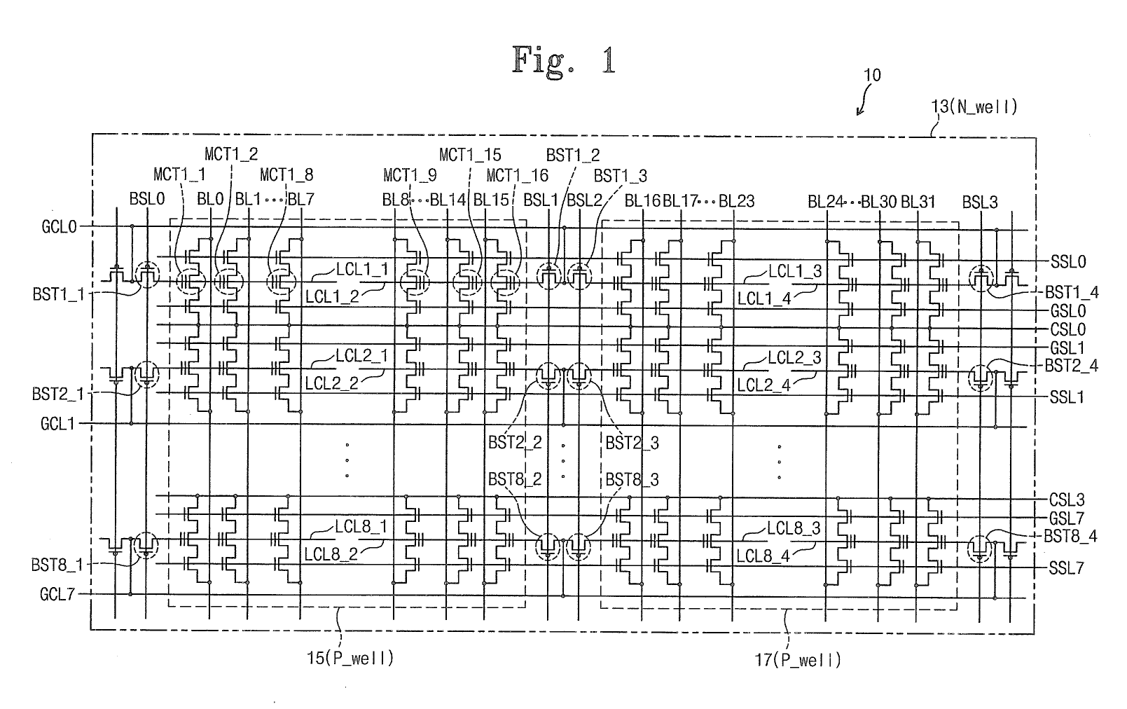

Referring now to FIG. 1, a byte-erasable electrically erasable programmable read only memory (EEPROM) 10 according to first embodiments of the present invention is illustrated as including first and second arrays of EEPROM cells. The first and second arrays are illustrated as being formed in first and second P-well semiconductor regions, respectively. The first P-well region is identified by the reference numeral 15 and the second P-well region is identified by the reference numeral 17. Both of these P-well regions are illustrated as being formed within a larger N-well region, which is identified by the reference numeral 13. The N-well region 13 is formed within a bulk semiconductor substrate (not shown). This semiconductor substrate may be an integrated circuit chip in some embodiments of the invention.

The EEPROM cells within the first and second arrays are three-transistor (3T) cells. Each of these 3T cells includes two NMOS transistors and one EEPROM transistor, connected as illustrated. In particular, each of the first and second arrays is illustrated as supporting a corresponding pair of 8×8 sub-arrays of EEPROM cells. The sixteen EEPROM transistors in row 1 of the first array are identified by the reference characters MCT1_1, MCT1_2, . . . , MCT1_16, where “MCT” designates “memory cell transistor.” The 8×8 sub-array on the left side of the first array spans columns 1-8, corresponding to bit lines BL0-BL7, and spans rows 1-8, corresponding to local control lines LCL1_1, LCL2_1, . . . , LCL8_1. The 8×8 sub-array on the right side of the first array spans columns 9-16, corresponding to bit lines BL8-15, and spans rows 1-8, corresponding to local control lines LCL1_2, LCL2_2, . . . , LCL8_2. Similarly, the 8×8 sub-array on the left side of the second array spans columns 17-24, corresponding to bit lines BL16-23, and spans rows 1-8, corresponding to local control lines LCL1_3, LCL2_3, . . . , LCL8_3. The 8×8 sub-array on the right side of the second array spans columns 25-32, corresponding to bit lines BL24-31, and spans rows 1-8, corresponding to local control lines LCL1_4, LCL2_4, . . . , LCL8_4.

The eight rows of EEPROM cells that span the first and second arrays are paired in groups so that rows 1-2 are electrically coupled to common source line CSL0, rows 3-4 are electrically coupled to common source line CSL1, rows 5-6 are electrically coupled to common source line CSL2, and rows 7-8 are electrically coupled to common source line CSL3, as illustrated. Moreover, the EEPROM cells in rows 1-8 are electrically coupled corresponding string selection lines SSL0-SSL7 and ground selection lines GSL0-GSL7, as illustrated. The local control lines LCL1_1, LCL1_2, LCL1_3 and LCL1_4 are electrically coupled to terminals of corresponding byte selection transistors BST1_1, BST1_2, BST1_3 and BST1_4, respectively, which have gate terminals electrically coupled to corresponding byte selection lines BSL0-BSL3. Each of these byte selection transistors BST1_, BST1_2, BST1_3 and BST1_4 is electrically coupled to a corresponding global control line GCL0. Similarly, the local control lines LCL2_1, LCL2_2, LCL2_3 and LCL2_4 are electrically coupled to terminals of corresponding byte selection transistors BST2_1, BST2_2, BST2_3 and BST2_4, respectively. Each of these byte selection transistors BST2_1, BST2_2, BST2_3 and BST2_4 is electrically coupled to a corresponding global control line GCL1. The local control lines, byte selection transistors and global control lines associated with rows 3-7 (not shown) are configured in a similar manner. Finally, the local control lines LCL8_1, LCL8_2, LCL8_3 and LCL8_4 are electrically coupled to corresponding byte selection transistors BST8_1, BST8_2, BST8_3 and BST8_4, respectively. Each of these byte selection transistors BST8_1, BST8_2, BST8_3 and BST8_4 is electrically coupled to a corresponding global control line GCL7.

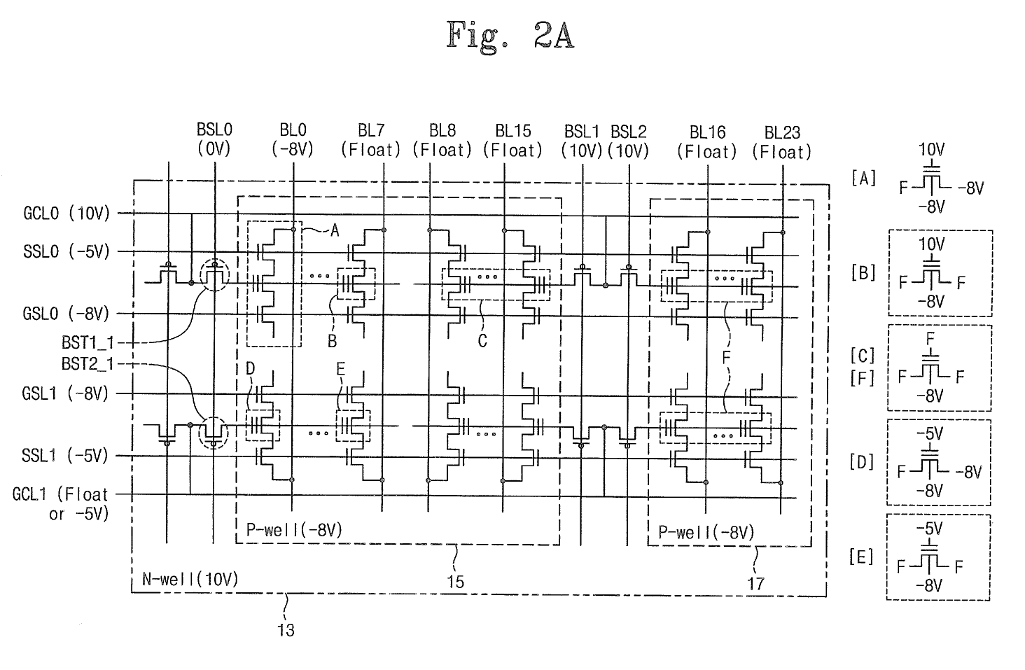

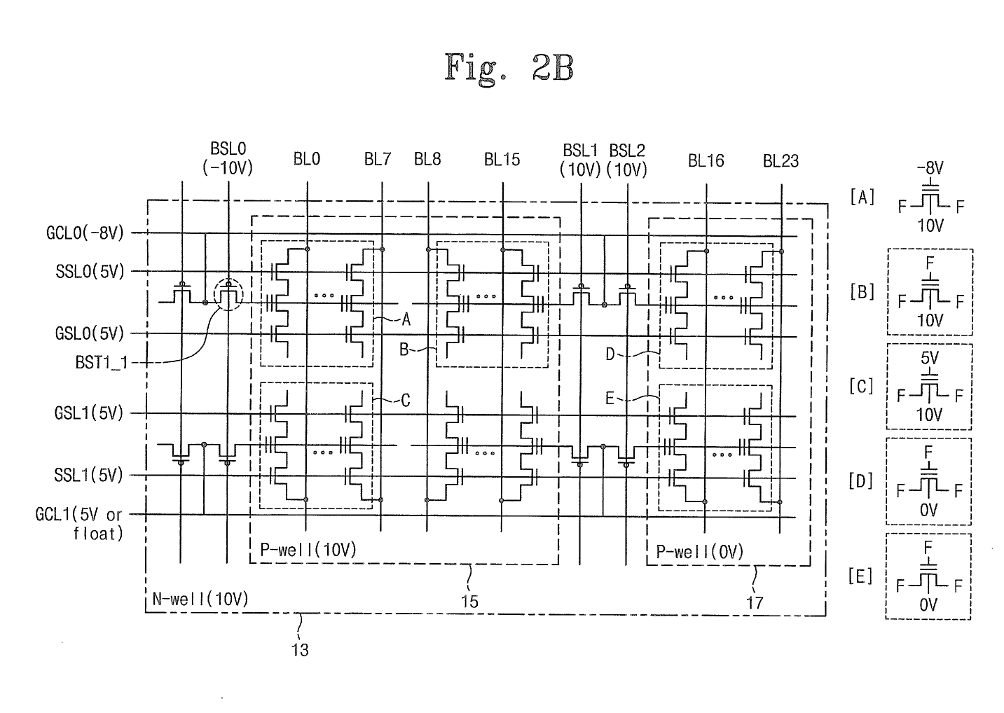

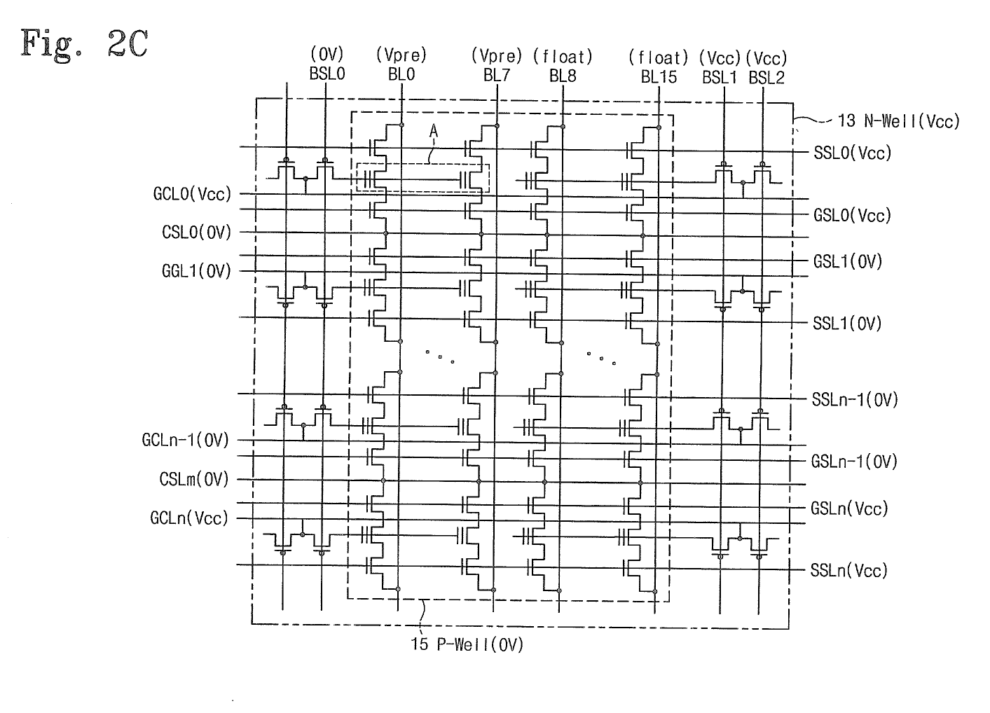

Operation of the byte-erasable EEPROM 10 of FIG. 1 will now be described more fully with respect to FIGS. 2A-2C. In particular, FIG. 2A illustrates an operation to program the EEPROM transistor MCT1_1 illustrated in FIG. 1. In FIG. 2A, the EEPROM transistor MCT1_1 is within a 3T EEPROM cell, which is designated by the reference label “A”. As illustrated by the right side of FIG. 2A, programming cell “A” can be achieved by establishing a voltage difference of 18 Volts between a channel region (at −8 Volts) and a control electrode (at +10 Volts) of the corresponding EEPROM transistor MCT1_1. The channel region is held at −8 Volts by setting the first P-well region 15 to a voltage of −8 Volts. The control electrode is electrically connected to the corresponding local control line, which is shown as LCL1_1 in FIG. 1. The local control line LCL1_1 is set to a +10 Volt level by turning on the PMOS byte selection transistor BST1_1 using a 0 Volt gate voltage (BSL0=0 Volts) and setting the N-well region 13 to +10 Volts. Turning on the byte selection transistor BST1_1 will cause the local control line LCL1_1 to be biased at the same voltage as the global control line GCL0 (i.e., +10 Volts). The source terminal of the selected EEPROM transistor MCT1_1 (within cell “A”) is set to a “floating” condition (F) by driving the ground selection line GSL0 at a voltage of −8 Volts. The drain terminal of the EEPROM transistor MCT1_1 is set to a voltage of −8 Volts by driving the bit line BL0 at a voltage of −8 Volts and turning on the corresponding NMOS string selection transistor by setting the string selection line SSL0 to −5 Volts (to thereby establish a gate-to-channel voltage of +3 Volts in the NMOS string selection transistor).

The EEPROM transistor MCT1_8, which is designated by the reference label “B”, is maintained in a program inhibited state by holding the source and drain terminals of the transistor MCT1_8 in a floating condition (F) to thereby prevent the 18 Volt difference between the control electrode and the channel region (i.e., P-well region 15) from charging the floating gate electrode extending therebetween. These floating conditions are achieved by holding the gate-to-channel voltages in the corresponding string selection and ground selection transistors at 0 Volts (GSL0=−8 Volts and P-well 15=−8 Volts; SSL0=−5 Volts and BL7=floating).

The bit lines BL8-BL15 and the local control line LCL1_2 are also held in floating conditions to thereby prevent the EEPROM transistors MCT1_9-MCT1_16, which are designated by reference label “C”, from being programmed. As illustrated, the local control line LCL1_2 may be held in a floating condition by holding the byte selection transistor BST1_2 in an “off” condition to thereby prevent the high voltage on the global control line GCL0 from being passed to the local control line LCL1_2. Thus, the byte of EEPROM cells designated by the reference label “C” can be independently programmed relative to the EEPROM cells designated by the reference labels “A” and “B”. The bit lines BL16-BL23 and the local control lines LCL1_3, LCL2_3, . . . , LCL8_3 may also be held in floating conditions to thereby prevent the EEPROM transistors in the second P-well region 17, which are designated by reference label “F”, from being programmed. Finally, the unselected byte of EEPROM transistors designated by the reference labels “D” and “E” may be disposed in a program inhibited condition by holding the global control line GCL1 in a floating condition or biasing it at a negative voltage (e.g., −5 Volts), which is passed to the local control line LCL2_1 via the byte selection transistor BST2_1.

FIGS. 1 and 2B illustrate operations to erase the byte of EEPROM transistors MCT1_1-MCT1_8 independently of erasing the other byte of EEPROM transistors MCT1_9-MCT1_16 located within the same P-well region 15. In particular, FIG. 2B identifies the EEPROM transistors MCT1_1-MCT1_8 by the reference labels “A” and identifies EEPROM transistors MCT1_9-MCT1_16 by the reference labels “B”. As shown on the right side of FIG. 2B, the EEPROM transistors in group “A” can be “byte-erased” by establishing an 18 Volt potential from the control electrode (−8 Volts) to the channel region (+10 Volts), which is shown as the first P-well region 15. The −8 Volt potential is established on the control electrodes by driving the local control line LCL1_1 from a global control line GCL0 that is biased at −8 Volts and by turning on the PMOS byte selection transistor BST1_1. In contrast, the EEPROM transistors in group “B” do not undergo a byte erase operation because the control electrodes for these transistors are held in a floating condition (F) by virtue of the fact that the corresponding byte selection line BSL1 is held at +10 Volts to thereby turn off the byte selection transistor BST1_2.

In addition, The EEPROM transistors identified by the reference labels “C”, which are also located within the first P-well region 15, do not undergo an erase operation because the corresponding global control line GCL1 (and local control line LCL2_1) is driven at a potential of +5 Volts (or floated). Thus, as illustrated by the right side of FIG. 2B, for the case of the EEPROM transistors within group “C”, only a 5 Volt potential is established between the corresponding control electrodes (at +5 Volts) and the corresponding channel regions (at +10 Volts). Finally, the EEPROM transistors identified by the labels “D” and “E” are precluded from undergoing an erase operation by virtue of the fact that the corresponding byte selection line BSL2 is held at +10 Volts, thereby turning off the byte selection transistors BST1_{—}3, . . . , BST8_3, and the second P-well 17 is held at 0 Volts.

FIGS. 1 and 2C illustrate bias conditions that support operations to read an 8-bit byte of data from the EEPROM transistors MCT1_1-MCT1_8, which are identified by the reference label “A”. These bias conditions also preclude reading of data from the other EEPROM transistors located within the N-well 13. As shown by FIG. 2C, the eight bit lines BL0-BL7 are initially precharged to a positive precharge voltage (Vpre) and then a positive global control line voltage (Vcc) is applied to the global control line GCL0. This positive voltage of Vcc is passed from the global control line GCL0 to the corresponding local control line associated with the group A EEPROM transistors by turning on the byte selection transistor BST_1. The byte selection transistor BST1_1 may be turned on by biasing the N-well region 13 at a positive voltage (shown as Vcc) and setting the byte selection line BSL0 at 0 Volts to thereby establish a negative gate-to-channel voltage across the byte selection transistor BST1_1. In addition, the NMOS string selection transistors and NMOS ground selection transistors for the group “A” EEPROM transistors are enabled to support a read operation by driving the string selection line SSL0 and GSL0 at a positive voltage (Vcc), which establishes a positive gate-to-channel voltage relative to the P-well region 15. In response to these applied voltages, a bit line sense amplifier (not shown) will evaluate changes in the voltages of the initially precharged bit lines BL0-BL7 to determine the states (programmed (cell data=0) or erased (cell data=1)) of the group “A” EEPROM transistors.

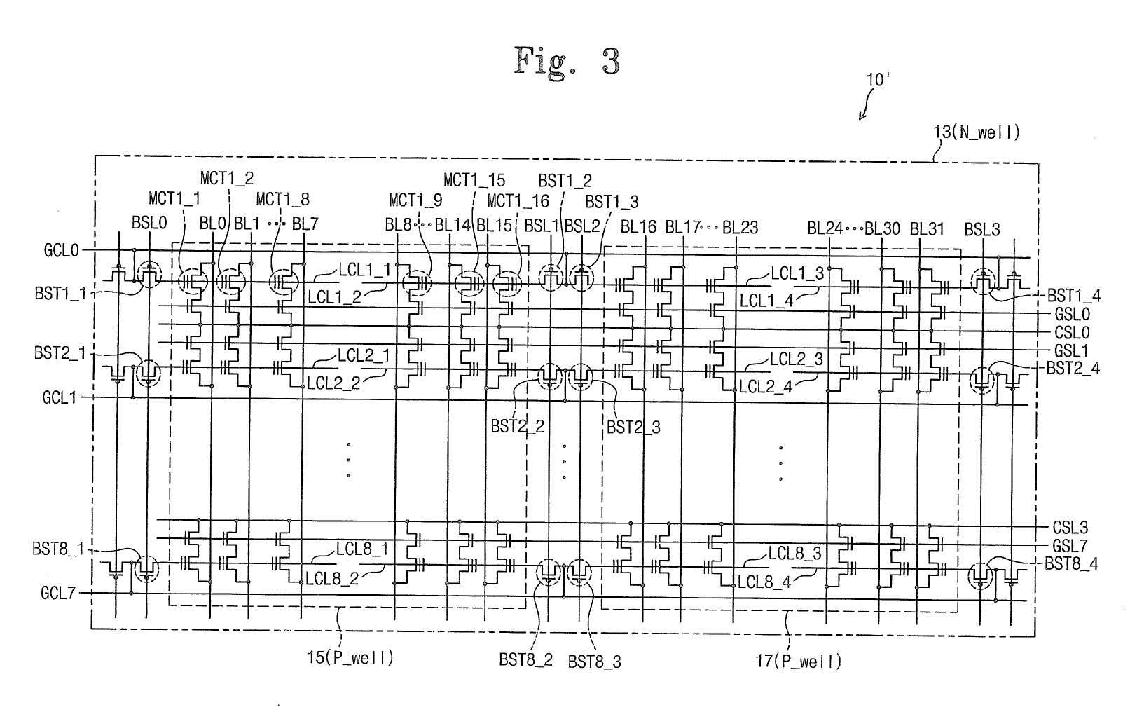

Referring now to FIG. 3, a byte-erasable electrically erasable programmable read only memory (EEPROM) 10′ according to a second embodiment of the present invention is illustrated as including two-transistor (2T) EEPROM cells. Each of these 2T cells includes one NMOS transistor and one EEPROM transistor, connected as illustrated. In contrast to the EEPROM 10 of FIGS. 1 and 2A-2C, the EEPROM 10′ of FIG. 3 does not include any NMOS string selection transistors or string selection lines. Otherwise, the EEPROM 10′ of FIG. 3 is equivalent to the EEPROM 10 of FIG. 1.

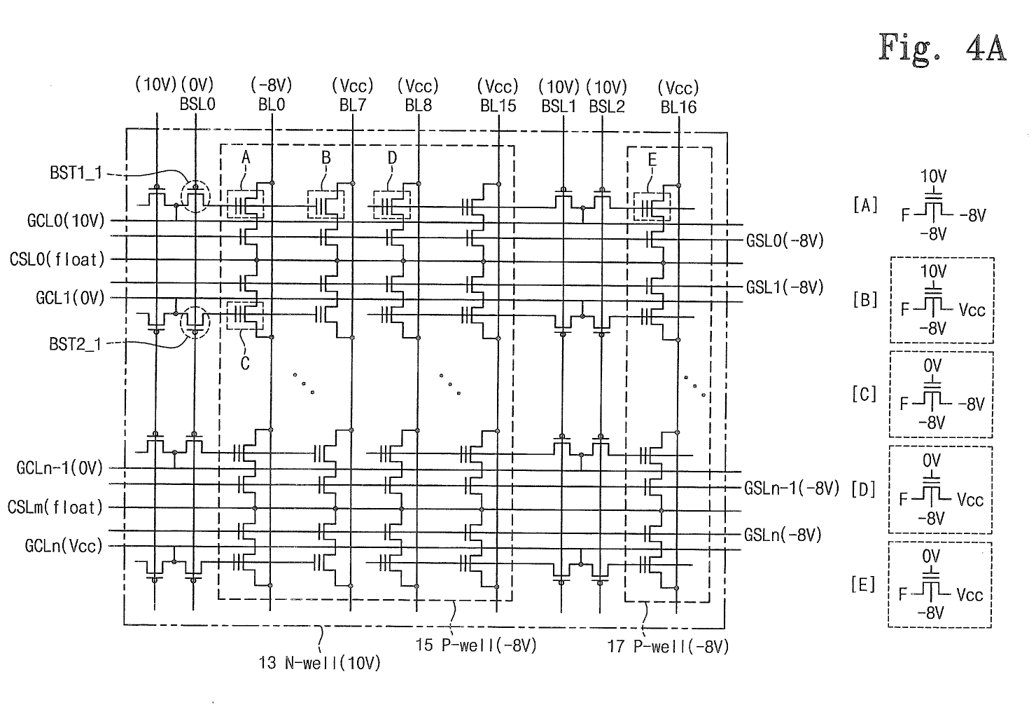

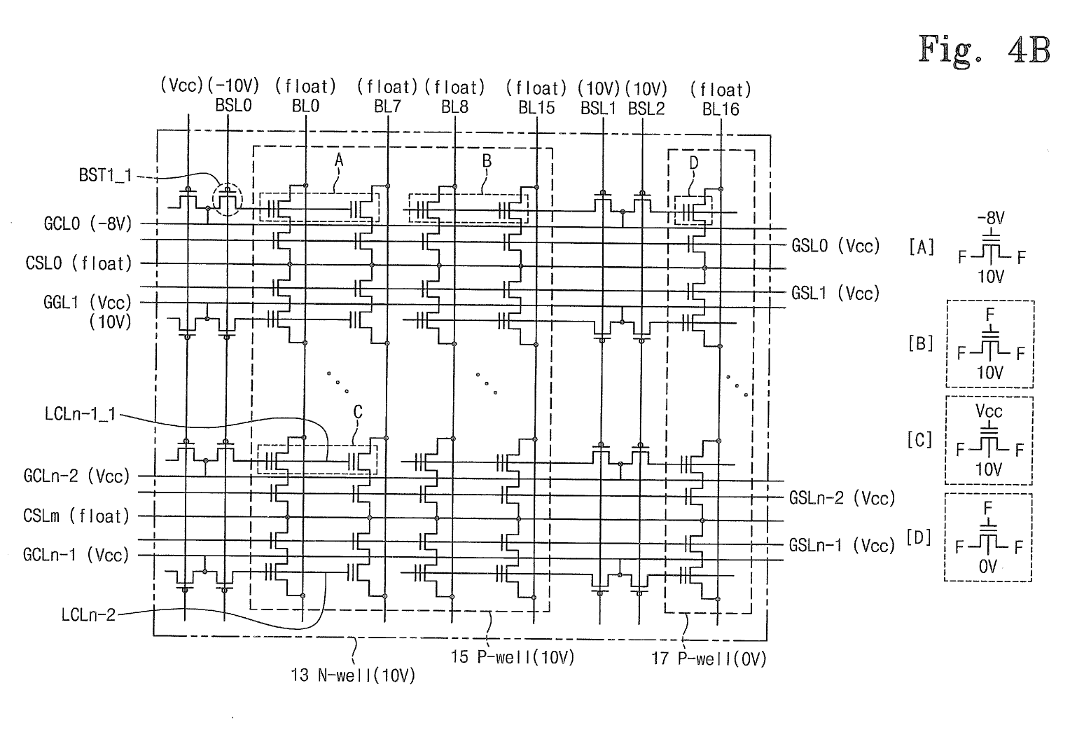

Operation of the EEPROM 10′ during programming and erasing will now be described more fully with respect to FIGS. 3 and 4A-4B. In particular, FIG. 4A illustrates the bias conditions necessary to program the EEPROM transistor highlighted with the reference label “A”. As illustrated on the right side of FIG. 4A, these bias conditions include establishing an 18 Volt potential from the channel region to the control electrode of the EEPROM transistor “A” and biasing the corresponding bit line BSL0 at −8 Volts. The channel region is set to an 8 Volt potential by setting the voltage of the first P-well 15 at −8 Volts. The control electrode is set to a potential of +10 Volts by driving the global control line GCL0 at +10 Volts and turning on the byte selection transistor BST1_1 by setting the byte selection line BSL0 to 0 Volts while the N-well region 13 is biased at +10 Volts. In contrast, the EEPROM transistor highlighted with the reference label “B” is maintained in its initially erased state by setting the corresponding bit line BL7 to a positive power supply voltage (e.g., Vcc). Thus, as illustrated by the right side of FIG. 4A, the EEPROM transistor “B” does not undergo a program operation because both the control electrode and drain terminal are held at positive voltages (e.g., 10 Volts and Vcc). Similarly, the EEPROM transistor highlighted with the reference label “C” is precluded from undergoing a program operation by driving its control electrode at 0 Volts. This is achieved by driving the global control line GCL1 at 0 Volts and turning on the byte selection transistor BST2_1. The EEPROM transistor “D” within the first P-well region 15 and the EEPROM transistor “E” within the second P-well region 17 are similarly precluded from undergoing program operations by driving their corresponding bit lines (BL8 and BL16) at positive voltages (Vcc) and driving their corresponding control electrodes at 0 Volts (LCL1_{—}2=0 Volts and LC1_{—}3=0 Volts). Thus, as illustrated by FIG. 4A, bias conditions that support programming may be modified relative to the bias conditions of FIG. 2A in order to account for a reduction in EEPROM cell size (i.e., reduction from 3T cell to 2T cell).

FIG. 4B illustrates bias conditions that support operations to erase one byte of EEPROM cells, shown by reference label “A”, but avoid erasure of other bytes of EEPROM cells located within the same P-well region 15 (reference labels “B” and “C”) and an adjacent P-well region 17 (reference label “D”). As illustrated on the right side of FIG. 4B, an 18 Volt potential may be established between the control electrodes and the channel regions of the group A EEPROM cells by driving the global control line GCL0 at −8 Volts and turning on the byte selection transistor BST1_1 so that the local control line LCL1_1 is held at −8 Volts. In addition, the first P-well region 15 is held at +10 Volts so that charge accumulated in any of the floating gate electrodes of any of the group A EEPROM cells can be withdrawn. The group B EEPROM cells are precluded from undergoing an erase operation by disposing the local control line LCL1_2 (see, FIG. 3) in a floating condition by turning off the byte selection transistor BST1_2. The group C EEPROM cells are precluded from undergoing an erase operation by driving the corresponding global control line GCLn-2 (e.g., GCL6) and the corresponding local control line LCLn-1_1 (e.g., LCL7_1) at a positive voltage (Vcc), while holding the first P-well region 15 at +10 Volts. Finally, the group D EEPROM cells are precluded from undergoing an erase operation by biasing the second P-well region 17 at 0 Volts and disposing the corresponding local control line LCL1_3 (see, FIG. 3) in a floating state.

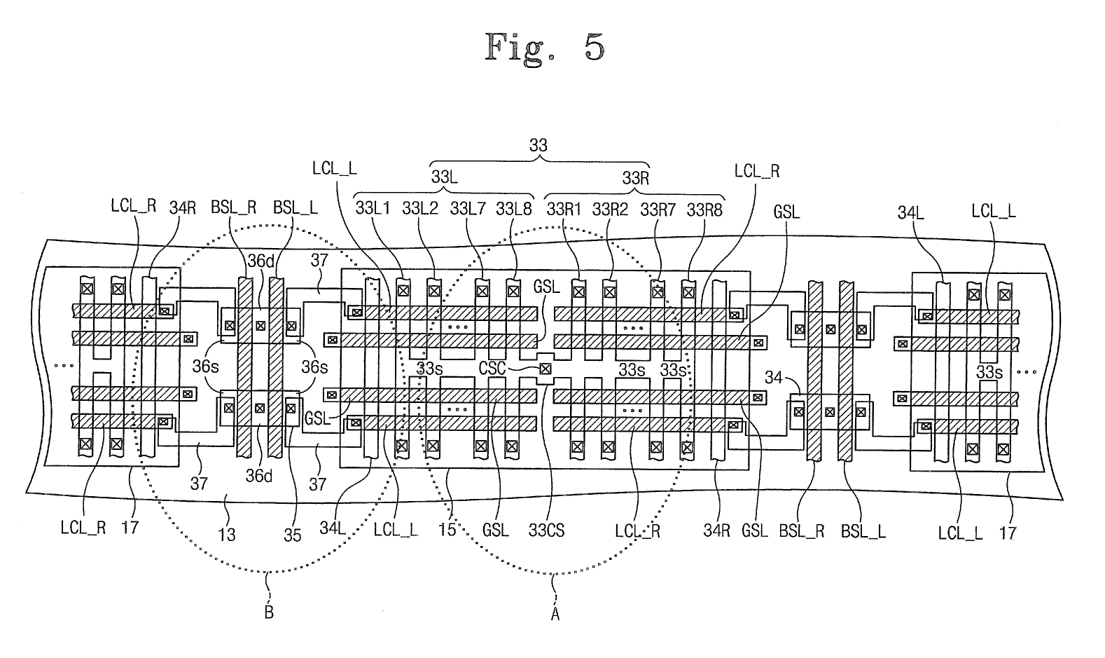

Referring to FIG. 5, a layout schematic of the programmable read only memory (EEPROM) 10′ of FIGS. 3 and 4A-4B will now be described. In particular, FIG. 5 illustrates an N-well region 13 containing a plurality of P-well regions 15 and 17. The illustrated portion of the central P-well region 15 contains two consecutive rows of 2T EEPROM cells that span 16 columns. For purposes of discussion herein, these two rows will be treated as the first two rows illustrated on the left side of FIG. 3, which are disposed within the P-well region 15. The reference labels LCL_R (“R”=right side of corresponding P-well region) within the central P-well region 15 correspond to the local control lines LCL1_2 and LCL2_2 in FIG. 3 and a reference labels LCL_L (“L”=left side of corresponding P-well region) within the central P-well region 15 correspond to the local control lines LCL1_1 and LCL2_1. The reference labels GSL within the central P-well region 15 correspond to gate line segments attached to ground selection lines GSL0 and GSL1. The region 33, which includes left side region 33L and right side region 33R, includes the layout pattern of a plurality of N-type diffusion regions (representing source/drain regions of the NMOS transistors and EEPROM transistors). These N-type diffusion regions are identified by the reference labels 33L1-33L8 and 33R1-33R8. The reference labels 33s and 33CS identify the layout pattern of the joined N-type diffusion regions that are connected to the common source line CSL0 (see FIG. 3) at the common source contact via CSC.

The layout reference 37 represents an electrically conductive wiring pattern that electrically connects an end of a corresponding local control line to a source terminal of a corresponding byte selection transistor, which is located within the N-well region 13. The layout reference 36s corresponds to the source regions of the byte selection transistors and the layout reference 36d corresponds to the drain regions of the byte selection transistors. The gate terminals of these byte selection transistors (see, e.g., BST1_1 in FIG. 3) are electrically connected to the metal byte selection lines identified by the references BSL_R and BSL_L.

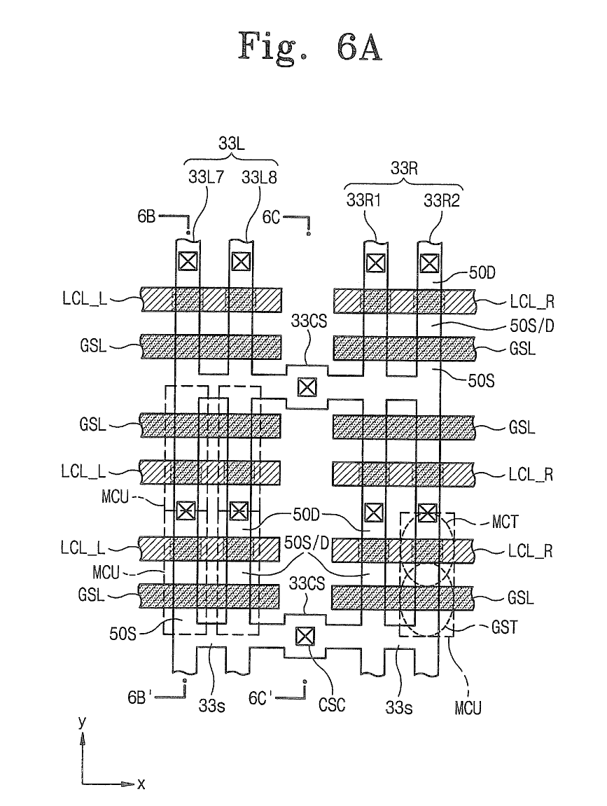

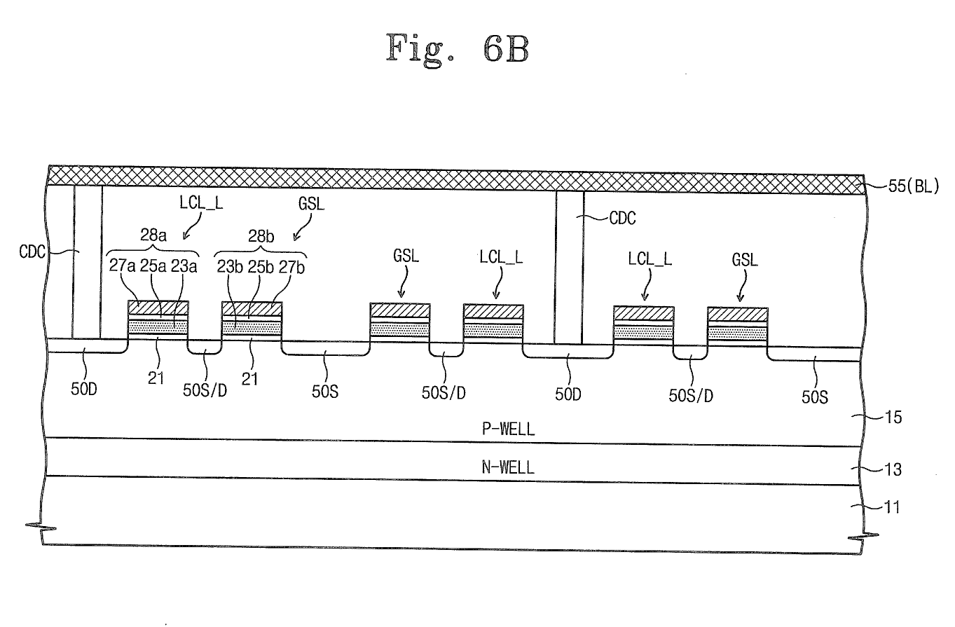

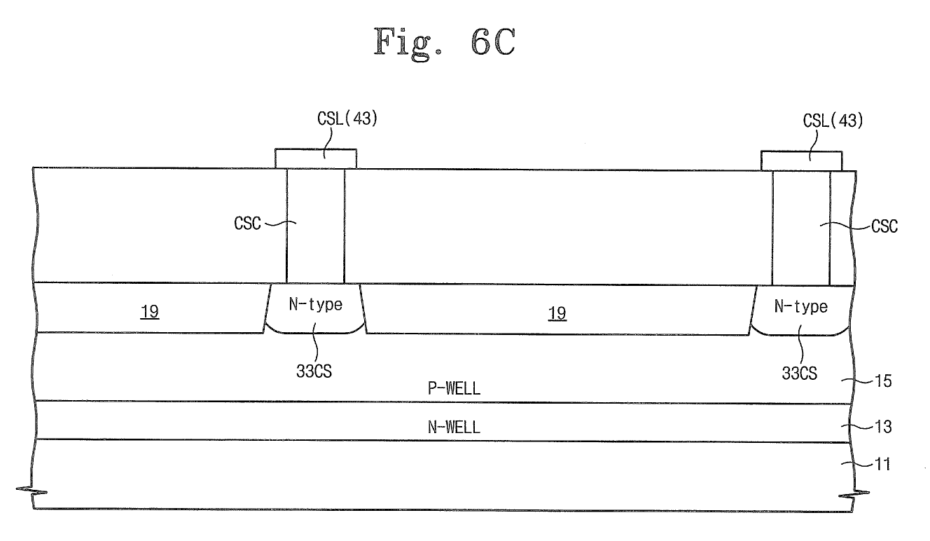

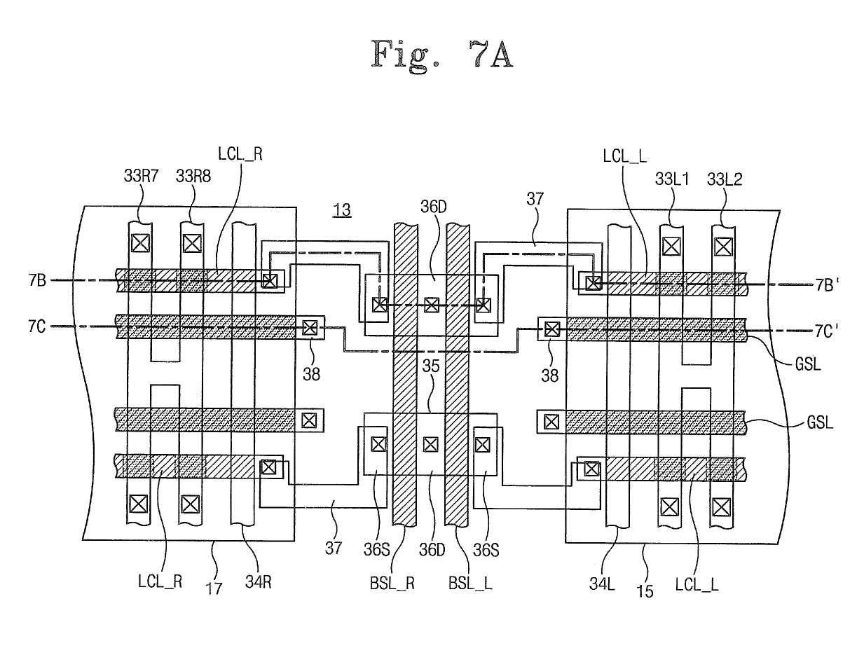

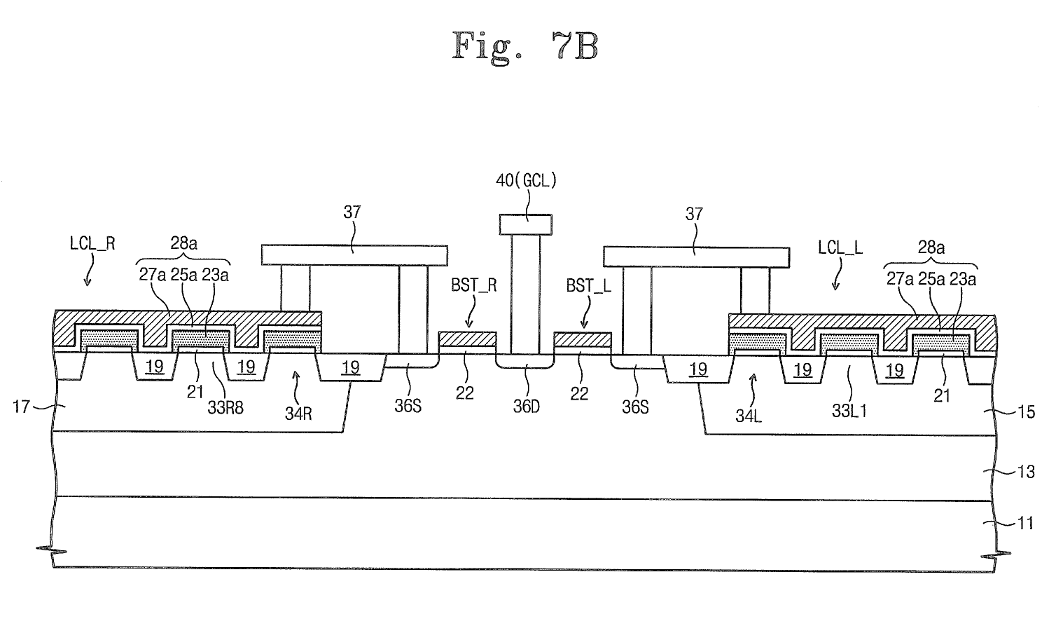

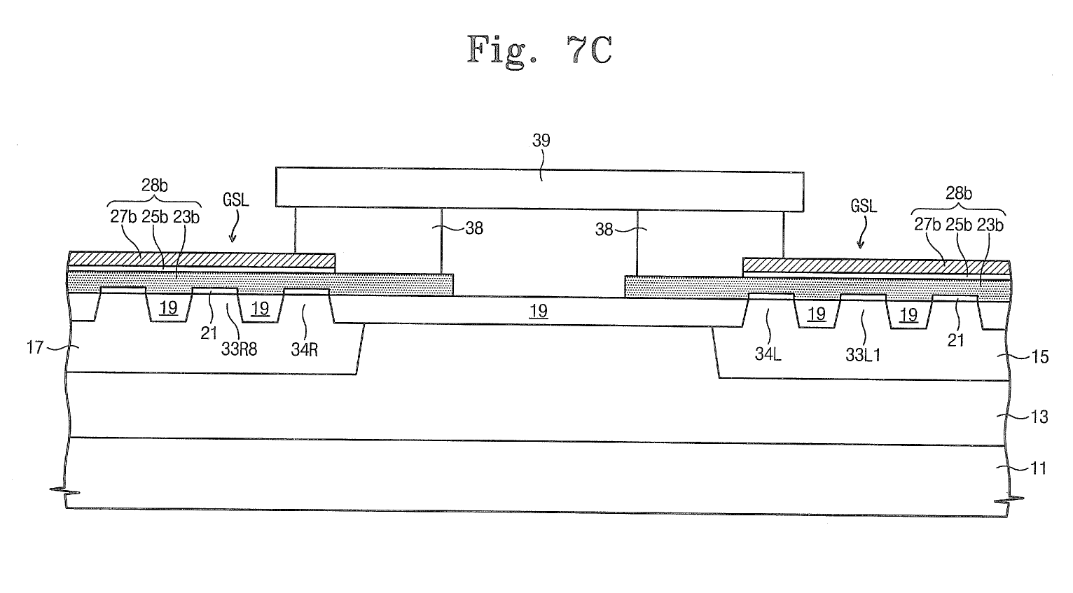

FIG. 5 also includes two highlighted regions A and B, which are identified by dotted lines. Region A is illustrated more fully by FIG. 6A and region B is illustrated more fully by FIG. 7A. In particular, FIG. 6A includes two cross-sectional lines 6B-6B′ and 6C-6C′ and the following additional reference labels: 50D, 50S, 50S/D, MCU, MCT and GST, which are not otherwise illustrated by FIG. 5. The reference label MCU identifies the layout area associated with each 2T EEPROM cell, the reference label MCT identifies the layout area associated with an EEPROM transistor within the 2T EEPROM cell and the reference label GST identifies the layout area associated with a ground select transistor (which has a gate electrode connected to corresponding ground selection lines GSL).

FIG. 6B illustrates a cross-sectional view of a portion of the EEPROM 10′ of FIG. 3, taken along line 6B-6B′ in FIG. 6A. As illustrated by FIG. 6B, a bit line 55 is vertically coupled by electrically conductive vias CDC to corresponding N-type drain regions 50D of EEPROM transistors 28a, which are located within a first P-well region 15. This first P-well region 15 is located within a larger N-well region 13. This N-well region 13 may be a deep N-type diffusion region within a semiconductor substrate 11. Each EEPROM transistor within a corresponding MCT layout region includes a control electrode 27a, which is part of a longer local control line (LCL_L), a floating gate electrode 23a, a tunnel oxide layer 21, an inter-electrode insulating layer 25a and source/drain regions (50D and 50S/D). Each ground select transistor 28b within a corresponding GST layout region includes a vertical dual-gate structure including a gate insulating layer 21 and conductive regions 23b and 27b, which are electrically connected together (in a third dimension, not shown). The insulating region 25b does not preclude all contact between the conductive regions 23b and 27b. The conductive regions 23b and 27b collectively form a portion of the ground select line GSL. Referring now to FIG. 6C, a pair of shallow trench isolation (STI) regions 19 are illustrated along with N-type diffusion regions 33CS, which electrically connected the source regions 50s of adjacent GSTs. These diffusion regions 33CS are connected by electrically conductive vias CSC to respective common source lines CSL 43.

FIG. 7A, which is an enlarged layout view of region B in FIG. 5, includes an additional reference 35, which identifies an N-type diffusion region pattern (e.g., an implant mask pattern) from which source and drain regions 36S and 36D are defined (e.g., after implant and diffusion/drive-in anneal). Regions 34R and 34L represent dummy diffusion patterns associated with dummy transistors that provide a vertical support for a via contact to the corresponding wiring patterns 37 (see FIG. 7B) and 39 (see FIG. 7C). FIG. 7A also includes two cross-sectional lines 7B-7B′ and 7C-7C′ that highlight the layout and cross-sectional construction of a plurality of EEPROM transistors and ground selection transistors (GSTs), respectively. In particular, FIG. 7B illustrates the spaced-apart P-well regions 15 and 17 within a larger N-well region 13. The P-well regions contain patterned shallow trench isolation regions 19, which provide local electrical isolation of adjacent transistors. On the left side of FIG. 7B, the local control line (LCL_R) is illustrated as spanning a plurality of EEPROM transistors 28a and the dummy transistor (identified by region 34R). The wiring pattern 37 provides an electrical jumper connection to a source region 36S of a corresponding byte selection transistor BST_R having a gate electrode with underlying gate insulating layer 22. The drain region 36D of the byte selection transistor BST_R is electrically connected to a corresponding global control line (GCL), which is identified by the reference label 40. Similarly, on the right side of FIG. 7B, the local control line (LCL_L) is illustrated as spanning a plurality of EEPROM transistors 28a and the dummy transistor (identified by region 34L). The wiring pattern 37 provides an electrical jumper connection to a source region 36S of a corresponding byte selection transistor BST_L. The drain region 36D of the byte selection transistor BST_L is commonly connected to the drain region 36D of the adjacent byte selection transistor BST_R and the global control line 40.

FIG. 7C highlights the layout and cross-sectional construction of a plurality of ground selection transistors 28b having gate electrodes that are linked together along a corresponding ground selection line GSL. In FIG. 7C, the dummy transistors at the locations identified by reference numerals 34R and 34L extend underneath electrically conductive vias 38 that are joined together by a ground selection line segment 39 (omitted from FIG. 7A, but shown in FIG. 7C). The ground selection line segment(s) 39 links the spaced-apart ground selection lines into a continuous wiring pattern that spans multiple P-well regions, as illustrated by FIG. 3.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A memory device, comprising:
a semiconductor substrate including a first well of a first conductivity type and a second well of a second conductivity type, the second well being within the first well;
a memory cell array including a plurality of memory cells within the second well, the memory cell array including a first and a second group of byte number memory cells in a respective row of the memory cell array; and
a first and a second byte selection transistors in the first well and electrically coupled to first and second groups of byte number memory cells, respectively.

2. The memory device of claim 1, wherein the first byte selection transistor is located at one side of the second well and the second byte selection transistor is located at the second side of the second well, the second side being opposite to the first side.

3. The memory device of claim 1, wherein each of the memory cells comprises a first bit selection transistor, a memory cell transistor and a second bit transistor serially connected along a column direction;
wherein each row of the memory cell array first group of byte number memory cell transistors and second group of byte number memory cell transistors, control gates of the first group of byte number memory cell transistors being connected to form a first local control line, and control gates of the second group of byte number memory cell transistors being connected to form a second local control line; and
wherein the first local control line is connected to the first byte selection transistor, and the second local control line is connected to the second byte selection transistor.

4. The memory device of claim 3, further comprising:
a bit line electrically connected to the first bit selection transistors arranged in the column direction;
a common source line electrically connected to the second bit line selection transistors arranged in a row direction; and
a global control line electrically connected to byte selection transistors arranged in the row direction.

5. The memory device of claim 1, wherein each of the memory cells comprises a bit selection transistor and is serially connected along a column direction;
wherein each row of the memory cell array comprises a first group of byte number memory cell transistors and a second group of byte number memory cell transistors, control gates of the first group of byte number memory cell transistors being connected to form a first local control line, and control gates of the second group of byte number memory cell transistors being connected to form a second local control line; and
wherein the first local control line is connected to the first byte selection transistor, and the second local control line is connected to the second byte selection transistor.

6. The memory device of claim 5, further comprising:
a bit line electrically connected to memory cell transistors arranged in the column direction;
a common source line electrically connected to bit selection transistors arranged in the column direction; and
a global control line electrically connected to byte selection transistors arranged in the column direction.

7. The memory device of claim 1, wherein the first conductivity is n-type and the second conductivity is p-type.

8. A memory device, comprising:
a first well in a semiconductor substrate;
a second well within the first well;
a memory cell array including a plurality of memory cells arranged in a row and a column, each of the memory cells including a first bit selection transistor of a first conductivity type, a memory cell transistor of the first conductivity type and a second bit selection transistor of the first conductivity type; and
a plurality of byte selection transistors within the first well, each of the byte selection transistors being electrically connected to byte number memory cell transistors in a respective row of the memory cell array.

9. The memory device of claim 8, wherein a control gate of byte number memory cell transistors in a respective row are connected so as to form a first local control line and a second local control line in the respective row, the first local control line and the second local control line are electrically connected to different byte selection transistors, respectively.

10. The memory device of claim 9, further comprising:
a plurality of global control lines, each of the plurality of global control lines being electrically connected to byte selection transistors arranged in a row direction;
a plurality of bit lines, each of the bit lines being electrically connected to first bit selection transistors arranged in a row direction; and
a plurality of common source lines, each of the common source lines being electrically connected to second bit selection transistors arranged in the row direction.

11. The memory device of claim 9, wherein the memory cells are programmed by F-N tunneling when a negative voltage is applied to a selected second well, a positive voltage is applied to a selected global control line, a voltage lower than the positive voltage applied to the selected global control line is applied to a non-selected global control line or the non-selected global line is floated, a selected byte selection transistor is turned on and a non-selected byte selection transistor is turned off, the first bit selection transistor is turned on such that the same voltage as the negative voltage applied to the selected second well is applied to a selected bit line, and a voltage higher than that applied to the negative voltage applied to the selected second well is applied to a non-selected bit line.

12. The memory device of claim 9, wherein the memory cells are erased by F-N tunneling when a positive voltage is applied to a selected second well, a negative voltage is applied to a selected global control line, a voltage higher than the negative voltage applied to the selected global control line is applied to a non-selected global control line or the non-selected global line is floated, a selected byte selection transistor is on state and a non-selected byte selection transistor is turned off, and the first bit selection transistor and the second byte transistor are turned off.

13. The memory device of claim 9, wherein the first well is n-type and the second well is p-type.

14. A memory device, comprising:
a first well of a first conductivity type in a substrate;
a plurality of spaced apart second wells of a second conductivity type within the first well, each of the plurality of spaced apart second wells including a memory array including a plurality of memory cells arranged in a row and a column; and
a first and a second byte selection transistors within the first well and both sides of each of the second wells, the first byte selection transistor and the second byte selection transistors being electrically coupled to first and second byte number memory cells of the same row of respective second well, respectively.

15. The memory device of claim 14, wherein the first conductivity is n-type and the second conductivity is p-type.

16. The memory device of claim 14, wherein each of the memory cells comprises a first bit selection transistor, a memory cell transistor and a second bit transistor serially connected along a column direction;
wherein each row of the memory cell array comprises a first group of byte number memory cell transistors and a second group of byte number memory cell transistors, control gates of the first group of byte number memory cell transistors being connected to form a first local control line, and control gates of the second group of byte number memory cell transistors being connected to form a second local control line; and
wherein the first local control line is connected to the first byte selection transistor, and the second local control line is connected to the second byte selection transistor.

17. The memory device of claim 16, wherein a distance between the first and the second local control line is narrower than a distance between adjacent second walls.

18. The memory device of claim 16, wherein a line width of the first and the second bit selection transistors is wider than a line width of the memory cell transistor.

19. A memory device, comprising:
a first well of a first conductivity in a substrate;
a plurality of spaced apart second wells of a second conductivity type within the first well;
a plurality of memory cells arranged in a row and a column, each of the plurality of memory cells including a memory cell transistor and a bit selection transistor serially connected in a column direction, a line width of the memory cell transistor and a line width of the bit section transistor are different from each other; and
a byte selection transistor within the first well and electrically coupled to byte number memory cell transistors in a respective row.

20. The memory device of claim 19, wherein a line width of the memory cell transistor is narrower than a line width of the bit selection transistor.

21. The memory device of claim 19, wherein gates of the bit selection transistors arranged in a row direction are connected to form a bit selection line, control gate of the byte number memory cell transistors arranged in the row direction are connected to form a local control line, and adjacent bit selection lines in the row are connected through a local interconnection, and wherein a contact between the local interconnection and the bit selection line is formed within the first well.
